(19) United States
(12) Patent Application Publication
(10) Pub. No.: US 2026/0159720 A1
(43) Pub. Date: Jun. 11, 2026

(54) CURABLE COMPOSITION AND INSULATING FILM

(71) Applicant: DUPONT ELECTRONICS, INC., WILMINGTON, DE (US)

(72) Inventors: CHU-YI LEE, HSINCHU (TW); YU-TE LIAO, HSINCHU (TW); YU-CHENG CHEN, HSINCHU (TW)

(21) Appl. No.: 19/408,963

(22) Filed: Dec. 4, 2025

Related U.S. Application Data
(60) Provisional application No. 63/730,236, filed on Dec. 10, 2024.

(51) Int. Cl. C09D 163/00; C09D 5/18; C09D 7/20; C09D 7/40; C09D 7/61; C09D 7/63; H05K 1/03; H05K 3/02

(52) U.S. Cl. CPC C09D 163/00; C09D 5/18; C09D 7/20; C09D 7/61; C09D 7/63; C09D 7/69; H05K 1/032; H05K 3/027

(57) ABSTRACT

The present disclosure provides a curable composition comprising: (a) maleimide resin; (b) cyanate ester; (c) polyphenylene ether oligomer; (d) thermoplastic elastomer; (e) epoxy resin; (f) curing catalyst; (g) additive; and (h) inorganic fillers, specifically boron nitride particles. The present disclosure also provides an insulating film comprising the aforementioned curable composition, which are particularly suited for manufacturing printed circuit boards (PCBs). The insulating film exhibit excellent electrical properties, including low dissipation factor (Df) and a low coefficient of thermal expansion (CTE). Furthermore, the insulating film provides significant advantages in reducing the production time in PCB manufacturing processes that involve a plasma etching step.

### FIELD OF THE DISCLOSURE

The disclosure relates in general to a curable composition containing boron nitride, and more particularly to an insulating film and/or a print circuit board comprising the same.

### BACKGROUND OF THE DISCLOSURE

Due to the current trend towards thinner and lighter electronic products, print circuit boards (PCBs) must have higher wiring density. PCB is generally composed of multiple insulating and conductive layers stacked on top of each other. To achieve high wiring density, through holes or blind holes are provided to connect circuit between different conductive layers.

The conventional via fabricating technology uses laser light as a drilling tool. The friction generated by drilling creates a resin smear on the channel walls. This smear must be removed to enable an optimal connection. Generally, a wet process is employed after laser drilling to remove smear and form suitable through holes. This wet process includes surface cleaning, swelling the smear, permanganate de-smear, and neutralization reaction. However, the waste liquid and waste water discharged in each step carry away a large amount of harmful substances, and may worsen the environment and impose damages to human's physical and mental health.

Compared to the subtractive or (modified) semi-additive process in PCB manufacturing, forming pattern and/or via by plasma etching is considered a more environmentally friendly process since it does not involve a wet process.

However, the etching rate of plasma etching is typically too slow to be cost-effective for manufacturing PCBs. For example, US Patent Publication No. 20220201853 A1 discloses using plasma etching to manufacture a multi-layer circuit structure having embedded circuit layers, but the material tested in this patent application demonstrated an etching rate of less than 1.0 μm/min.

In view of the above, there exists a need to develop new materials for PCB insulting layers and the ability to be treated with a plasma etching process brings overall benefits to the printed circuit board industry.

### SUMMARY

To solve the aforementioned problems, the present disclosure provides a novel resin composition for an insulating layer of PCB. PCB composed with this material has higher plasma etching rate without sacrificing its electrical and mechanical properties, such as dissipation factor (Df) and the coefficient of thermal expansion (CTE). The novel resin composition is a viable alternative to conventional PCB insulating layer.

According to one aspect of the present disclosure, a curable composition is provided. The curable composition comprises:
100 parts by weight of a maleimide resin;
30-150 parts by weight of a cyanate ester;
10-100 parts by weight of a polyphenylene ether oligomer;
2-75 parts by weight of a thermoplastic elastomer;
0.2-25 parts by weight of an epoxy resin;
0.02-15 parts by weight of a curing catalyst;
0.02-100 parts by weight of an additive; and
120-825 parts by weight of inorganic fillers comprising boron nitride particles having a median particle size of 10 μm or less.

According to the second aspect of the present disclosure, an insulating film comprising the aforementioned curable composition is also provided. The insulating film comprises sequentially a support film, a resin layer composed of the above curable composition, and a protective film. The resin layer has a thickness of 10 μm to 60 μm.

According to the third aspect of the present disclosure, a printed circuit board is also provided. The PCB comprises an insulating layer that is a cured product of the above curable composition or is made from the above insulating film.

### BRIEF DESCRIPTION OF THE DRAWINGS

FIG. 1 shows a section view of the testing coupon according to one embodiment of the present disclosure.

### DETAILED DESCRIPTION OF THE EMBODIMENTS

Before addressing details of embodiments described below, some terms are defined or clarified.

### Definitions

All publications, patent applications, patents and other references mentioned herein, if not otherwise indicated, are explicitly incorporated by reference herein in their entirety for all purposes as if fully set forth.

Unless otherwise defined, all technical and scientific terms used herein have the same meaning as commonly understood by one of ordinary skill in the art to which this disclosure belongs. In case of conflict, the present specification, including definitions, prevails.

Unless stated otherwise, all percentages, parts, ratios, etc., are by weight.

As used herein, the term “produced from” is synonymous to “comprising”. As used herein, the terms “comprises,” “comprising,” “includes,” “including,” “has,” “having,” “contains” or “containing,” or any other variation thereof, are intended to cover a non-exclusive inclusion. For example, a composition, process, method, article, or apparatus that comprises a list of elements is not necessarily limited to only those elements but may include other elements not expressly listed or inherent to such composition, process, method, article, or apparatus.

The transitional phrase “consisting of” excludes any element, step, or ingredient not specified. If in the claim, such a phrase would restrict the claim to the inclusion of materials other than those recited except for impurities ordinarily associated therewith. When the phrase “consisting of” appears in a clause of the body of a claim, rather than immediately following the preamble, it limits only the element set forth in that clause; other elements are not excluded from the claim as a whole.

The transitional phrase “consisting essentially of” is used to define a composition, method or apparatus that includes materials, steps, features, components, or elements, in addition to those literally discussed, provided that these additional materials, steps features, components, or elements do not materially affect the basic and novel characteristic(s) of the claimed disclosure.

The term “consisting essentially of” occupies a middle ground between “comprising” and “consisting of”.

The term “comprising” is intended to include embodiments encompassed by the terms “consisting essentially of” and “consisting of”. Similarly, the term “consisting essentially of” is intended to include embodiments encompassed by the term “consisting of”.

When an amount, concentration, or other value or parameter is given as either a range, preferred range or a list of upper preferable values and lower preferable values, this is to be understood as specifically disclosing all ranges formed from any pair of any upper range limit or preferred value and any lower range limit or preferred value, regardless of whether ranges are separately disclosed. For example, when a range of “1 to 5” is recited, the recited range should be construed as including ranges “1 to 4”, “1 to 3”, “1-2”, “1-2 & 4-5”, “1-3 & 5”, and the like. Where a range of numerical values is recited herein, unless otherwise stated, the range is intended to include the endpoints thereof, and all integers and fractions within the range.

Further, unless expressly stated to the contrary, “or” refers to an inclusive “or” and not to an exclusive “or”. For example, a condition A “or” B is satisfied by any one of the following: A is true (or present) and B is false (or not present), A is false (or not present) and B is true (or present), and both A and B are true (or present).

The disclosure is described in detail herein under.

The present disclosure relates to a curable composition comprises:
100 parts by weight of a maleimide resin;
30-150 parts by weight of a cyanate ester;
10-100 parts by weight of a polyphenylene ether oligomer;
2-75 parts by weight of a thermoplastic elastomer;
0.2-25 parts by weight of an epoxy resin;
0.02-15 parts by weight of a curing catalyst;
0.02-100 parts by weight of an additive; and
120-825 parts by weight of inorganic fillers comprising boron nitride particles having a median particle size of 10 μm or less.

In one embodiment of the present disclosure, the polyphenylene ether oligomer is free of a polyphenylene ether derivative having an N-substituted maleimide structure-containing group.

In one embodiment of the present disclosure, the inorganic filler is free of silica.

In one embodiment of the present disclosure, the curable composition is free of modifier selected from the group consisting of diallyl hexafluorobisphenol A, diallyl bisphenol A, diallyl phthalate, maleimide octasilsesquioxane, carbon fluoride nano tube, and montmorillonite.

In one embodiment of the present disclosure, the curable composition is free of polymerization initiator.

In one embodiment of the present disclosure, the curable composition comprises 30-100 parts by weight of a cyanate ester relative to a total of 100 parts by weight of a maleimide resin. In another embodiment of the present disclosure, the curable composition comprises 30-90 parts by weight of a cyanate ester relative to a total of 100 parts by weight of a maleimide resin. In another embodiment of the present disclosure, the curable composition comprises 30-70 parts by weight of a cyanate ester relative to a total of 100 parts by weight of a maleimide resin.

In one embodiment of the present disclosure, the curable composition comprises 120-825 parts by weight of inorganic fillers comprising boron nitride particles relative to a total of 100 parts by weight of a maleimide resin. In another embodiment of the present disclosure, the curable composition comprises 120-800 parts by weight of inorganic fillers comprising boron nitride particles relative to a total of 100 parts by weight of a maleimide resin. In another embodiment of the present disclosure, the curable composition comprises 150-700 parts by weight of inorganic fillers comprising boron nitride particles relative to a total of 100 parts by weight of a maleimide resin.

Non-limiting examples of maleimide resin comprise a maleimide with a biphenyl aralkyl backbone; a bismaleimide derived from a dimer diamine; a bismaleimide including 4,4′-diphenylmethane bismaleimide, 3,3′-diphenylmethane bismale-imide, 1,3 phenylene bismaleimide, 1,4 phenylene bismaleimide, m-xylenebismaleimide, p-xylenebismaleimide, 2,2′-bis[4-(4-maleimidophenoxy)phenyl]-propane, 3,3′-dimethyl-5,5′ diethyl-4,4′-diphenylmethane bismaleimide, 3,3′,5,5′-tetramethyldiphenylmethane bismaleimide, N,N′-(4-methyl-1,3-phenylene) bismaleimide, 1,6-bismaleimidohexane, 1,6′ bismaleimide-(2,2,4-trimethyl) hexane, or 4,4′-diphenyl ether bismaleimide, or a mixture thereof.

Non-limiting examples of cyanate ester comprise a difunctional or polyfunctional compound selected from the group consisting of 2,2-bis(4-cyanatophenyl) propane (bisphenol A-containing cyanate ester), bis(4-cyanatopheny) methane (bisphenol F-containing cyanate ester), dicyclopentadiene-containing cyanate ester, naphthalene-containing cyanate ester, phenolphthalein cyanate ester, adamantane cyanate ester, fluorene cyanate ester, phenol novolac type cyanate ester, and a combination thereof.

Non-limiting examples of polyphenylene ether oligomer comprise a polyphenylene ether oligomer terminated with an acrylate group, an epoxy group, a vinyl group, a vinylbenzyl ether, or a hydroxyl group. However, polyphenylene ether derivatives having an N-substituted maleimide structure-containing group are excluded from the present disclosure.

Non-limiting examples of thermoplastic elastomer comprise polybutadiene, ethylene-propylene-diene copolymer (EPDM), butadiene-styrene block copolymer, styrene-isoprene-styrene block polymer (SIS), styrene-ethylene-propylene-styrene block copolymer (SEPS), styrene-ethylene-butylene-styrene copolymer (SEBS), or modified products thereof. The above polymers/copolymers can be modified with carboxylic acid groups and/or maleic anhydride groups.

Non-limiting examples of epoxy resin comprise bisphenol A type epoxy, bisphenol F type epoxy, glycidyl amine type epoxy, biphenyl type epoxy, naphthalene type epoxy, anthracene type epoxy, fluorene type epoxy, biphenyl aralkylphenol type epoxy, dicyclopentadiene type epoxy, trihydroxyphenylmethane type epoxy, naphthol aralkyl type epoxy, phenol aralkyl type epoxy, phenol novolac type epoxy, cresol novolac type epoxy, bisphenol novolac type epoxy, naphthol-cresol novolac type epoxy, naphthalenediol novolac type epoxy, hydrogenated modified epoxy, halogen modified epoxy, or a combination thereof.

Non-limiting examples of the curing catalyst comprise an alkyl amine type catalyst, a pyridine type catalyst, an imidazole type catalyst, a piperidine type catalyst, a metal-based curing catalyst, or a combination thereof.

Non-limiting examples of the additive comprise adhesion promoter, antioxidant, colorant, defoamer, flame retardant, polymerization inhibitor, silane coupling agent, solvent, surface conditioner, thickener, ultraviolet absorber, or a combination thereof.

In one embodiment of the present disclosure, the additive is a flame retardant selected from the group consisting of a brominated flame retardant, a phosphorus flame retardant, a nitrogen flame retardant, and a combination thereof.

In one embodiment of the present disclosure, a brominated flame retardant is decabromodiphenyl ether, decabromodiphenyl ethane, brominated styrene or tetrabromophthalic acid amide.

In one embodiment of the present disclosure, a phosphorus flame retardant is inorganic phosphorus, phosphate compound, phosphoric acid compound, hypophosphorous acid compound, phosphorus oxide compound, phosphazene or modified phosphazene.

In one embodiment of the present disclosure, a phosphorus flame retardant is 9, 10-dihydro-9-oxa-10-phosphaphenanthrene-10-oxide (DOPO), 10-(2,5-dihydroxyphenyl)-9, 10-dihydro-9-oxa-10-phosphaphenanthrene-10-oxide (DOPO-HQ), or tris(2,6-dimethylphenyl) phosphorus.

In one embodiment of the present disclosure, a nitrogen flame retardant is triazine compound, cyanuric acid compound, isocyanic acid compound or phenothiazine.

In one embodiment of the present disclosure, the additive is a solvent comprising cyclohexanone, cyclopentanone, isophorone, methyl ethyl ketone, methyl isobutyl ketone, toluene, or a combination thereof.

The second aspect of the present disclosure is related to an insulating film for fabricating a printed circuit board. The insulating film comprising sequentially:
a support film;
a resin layer composed of the above curable composition; and
a protective film.

In one embodiment of the present disclosure, the resin layer has a thickness of 10 μm to 60 μm. In one embodiment of the present disclosure, the support film is a thermoplastic film having a thickness of 10 μm to 50 μm, or a metallic foil having a thickness of 1 μm to 25 μm. In one embodiment of the present disclosure, the protective film is a thermoplastic film has a thickness of 10 μm to 50 μm.

In one embodiment of the present disclosure, the support film and the protective film are each independently composed of a polymeric material selected from the group consisting of polyethylene, polypropylene, polyvinyl chloride, polyethylene terephthalate, polyethylene naphthalate, polycarbonate, and polyimide.

In one embodiment of the present disclosure, the support film is a metallic foil selected from the group consisting of Au, Ag, Cu, Al, and alloys thereof.

In one embodiment of the present disclosure, the resin layer is cured at 100° C. to 250° C. for 60 minutes to 240 minutes.

In one embodiment of the present disclosure, the resin layer after curing has a dissipation factor (Df) of 0.006 or less when measured at 10 GHz and 23° C.

In one embodiment of the present disclosure, the resin layer after curing has a coefficient of thermal expansion (CTE) of 40 ppm/K or less between 30° C. to 120° C.

In one embodiment of the present disclosure, the resin layer after curing has a plasma etching rate of 1 μm/min or more. In another embodiment of the present disclosure, the resin layer after curing has a plasma etching rate of 1.5 μm/min or more. The plasm etching is performed under a chamber pressure of 2 Pa (15 mtorr) by applying a radiofrequency (RF) power of 13.56 MHz, an ignition power of 8000 Watts, a DC bias of 3000 Watts setting with a gas mixture of oxygen, tetrafluoromethane (carbon tetrafluoride, CF4) and nitrogen at a ratio of 10:10:1, and a flow rate of 1050 mL/sec for 15 minutes.

The third aspect of the present disclosure is related to a printed circuit board comprising an insulating layer that is a cured product of the above curable composition or is made from the above insulating film.

In one embodiment of the present disclosure, the circuit is fabricated by a method comprising a plasma etching step for via and/or trench formation.

In one embodiment of the present disclosure, the method for forming the circuit is a semi-additive process (SAP) or a modified semi-additive process (mSAP).

### Composition and Film Preparation

The curable composition of the present disclosure comprises the following components: (a) maleimide resin; (b) cyanate ester; (c) polyphenylene ether oligomer; (d) thermoplastic elastomer; (e) epoxy resin; (f) a curing catalyst; (g) additive; and (h) inorganic fillers. In one non-limiting aspect, the composition aspect of the present disclosure may be prepared from the components listed in Table A below. Components (a) to (g) were mixed until fully dissolved to form a base. Then component (h): filler was added to the base, followed by using a rotary mixer to disperse uniformly. The composition was prepared into two different samples: resin coated copper (RCC) film structure and resin sheet structure for more test.

TABLE A

| | | Brand and | | |
|---|---|---|---|---|
| Type | Manufacturer | model name | Description | Properties |
| (a)maleimide resin | Nippon kayaku | MIR3000- | Biphenyl backbone | 70% in mixture solvent, |
| | | 70MT | multifunctional maleimide | Maleimide equivalent = |
| | | | | 400~460 g/eq. |
| (b)cyanate ester | Arxada | Primaset BA- | Bisphenol-A cyanate ester | Viscosity = 450 mPa-s at |
| resin | | 200 | oligomer | 80° C. |
| (c)PPE resin | Mitsubishi gas chemical | OPE2st-1200 | styrene-modified | 65% in Toluene |
| | | | polyphenylene ether resin | Mn = 1200 g/mol |
| (d)thermoplastic | Cray valley | Ricon154 | Polybutadiene Resin, rubber | Molecular weight (Mn) = |
| elastomer | | | | 9000 g/mol, |
| (e)epoxy | Nippon kayaku | NC3000H | biphenyl epoxy | Epoxy equivalent = 280~300 |
| | | | | g/eq |
| (f)catalyst | Nova materials | Lophine | 2,4,5-triphenyl-1H-imidazole | CAS No. 484-47-9 |
| (g)additive (Flame | Daihachi chemical | PX-200 | Phosphoric acid 1,3-phenylene | CAS No. 139189-30-3 |
| retardant) | | | tetrakis(2,6-dimethylphenyl) | |
| | | | ester, flame retardant | |
| (g)additive (solvent) | — | — | MEK | — |
| (g)additive (solvent) | — | — | toluene | — |
| (h)filler | Saint-Gobain | PCTP05 | BN(boron nitride) | D50 = 1.2 μm |
| (h)filler | Sukgyung AT | SG-SO0700 | Silica | D50 = 1.2 μm |
| support film | Mitsui | MT18FL | copper foil | — |
| protective film | Lintec | 38X | release agent-coated PET film | — |
| protective film | Oji Film | MA411 | OPP release film | — |

### Example 1

25.7 g of MIR3000-70MT (70 wt % of maleimide resin in MEK Toluene mixture solution), 12 g of Primaset BA-200 (cyanate ester resin), 12.3 g of OPE2st 1200 (65 wt % of PPE resin in toluene solution), 5 g of Ricon 154 (thermoplastic elastomer), 2 g of NC3000H (epoxy), 0.6 g of Lophine (catalyst), 5 g of PX-200 (additive), 10 g of MEK (solvent), and 10 g of toluene (solvent) were mixed and stirred until fully dissolved. Subsequently, 75 g of PCTP05 (filler) was added, and the mixture was dispersed uniformly using a high-speed rotary mixer to prepare a resin varnish.

The resulting resin varnish was coated onto a supporting film MT18FL-3 μm (two-layered copper foil with an upper layer having a thickness of 3 μm and the lower layer having a thickness of 18 μm) using suitable quadruple film applicators (purchased from GMA Machinery, Taiwan) on an automatic coater (model Coatmaster 510, purchased from Erichsen GmbH) at a coating speed of approximately 60 mm/s. The coated film was then dried at 100° C. for 3 minutes in a circulation oven (model DCM704, purchased from Channel Instruments, Taiwan). After drying, the film was covered with 38× (protective film), forming a Resin Coated Copper (RCC) film structure sample.

Additionally, the mixed varnish was coated onto 38× (protective film) and dried at 100° C. for 3 minutes. The dried film was then covered with MA411 (protective film), forming a resin sheet structure.

Thickness of the resin composition layer was 30 μm in the two structures above.

### Example 2

The resin composition of example 1, wherein the amount of PCTP05 (filler) is 50 g.

### Example 3

The resin composition of example 1, wherein the amount of PCTP05 (filler) is 34 g.

### Comparative Example 1

The resin composition of example 1, wherein filler is replaced by SG-SO700 (Silica) and the amount is 95 g.

### Comparative Example 2

The resin composition of example 1, wherein filler is replaced by SG-SO700 and the amount is 50 g.

### Comparative Example 3

The resin composition of example 1, wherein filler is replaced by SG-SO700 and the amount is 34 g.

The components of above Examples and Comparative Examples are listed in Table B. The materials are listed by their dried mass in the table B. The abbreviation “E” stands for “Example”, and “CE” stands for “Comparative Example”. The Examples and Comparative Examples were prepared in a similar manner. The difference between Examples and Comparative Examples lies in the filler. Examples 1-3 uses boron nitride as filler while the Comparative Examples 1-3 uses silica.

TABLE B

| | Brand and model | | | | | | | |
|---|---|---|---|---|---|---|---|---|
| Type | name | Description | E1 | E2 | E3 | CE1 | CE2 | CE3 |
| (a)maleimide resin, g | MIR3000-70MT | Maleimide | 18 | 18 | 18 | 18 | 18 | 18 |
| (b)cyanate ester resin, g | Primaset BA-200 | cyanate ester | 12 | 12 | 12 | 12 | 12 | 12 |
| (c)PPE resin, g | OPE2st-1200 | polyphenylene | 8 | 8 | 8 | 8 | 8 | 8 |
| (d)thermoplastic | Ricon154 | polybutadiene rubber | 5 | 5 | 5 | 5 | 5 | 5 |
| elastomer, g | | | | | | | | |
| (e)epoxy, g | NC3000H | biphenyl epoxy | 2 | 2 | 2 | 2 | 2 | 2 |
| (f)catalyst, g | Lophine | 2,4,5-triphenyl-1H-imidazole | 0.6 | 0.6 | 0.6 | 0.6 | 0.6 | 0.6 |
| (g)additive, g | PX200 | Flame retardant | 5 | 5 | 5 | 5 | 5 | 5 |
| (g)additive, g | MEK | Solvent | 10 | 10 | 10 | 10 | 10 | 10 |
| (g)additive, g | toluene | Solvent | 10 | 10 | 10 | 10 | 10 | 10 |
| (h)filler, g | PCTP05 | BN, D50 = 1.2 μm* | 75 | 50 | 34 | | | |
| (h)filler, g | SG-SO700 | Silica, D50 = 1.2 μm | | | | 95 | 50 | 34 |

| | | | | | | |
|---|---|---|---|---|---|---|
| parts by weight of filler** | 416.7 | 277.8 | 188.9 | 527.8 | 277.8 | 188.9 |

*The median particle size (D50) of boron nitride is measured by a laser scattering particle size distribution analyzer
**The parts by weight of filler based on maleimide resin being 100 parts by weight.

### Measuring Plasma Etching Rate of the RCC Film

### Test Coupon Preparation

RCC films of above Examples and Comparative Examples were further processed as follows to prepare a coupon for plasma etching testing:
Lamination: RCC film of size 15 cm×20 cm was laminated on a CZ-8100 (pre-treatment solution made by MEC) pretreated EM526 H/H core board (15 cm×20 cm, 0.6 mm thick) by vacuum laminator. The vacuum laminator was heated to 100° C. and vacuumed for 30 seconds, then pressured to 7 kgf/cm² for 90 seconds at 100° C.
Curing: The laminated sample was cured in an air flow oven with 130° C. for 30 minutes; 180° C. for 30 minutes; and then 200° C. for 90 minutes.
Copper Removal: After curing, the supporting film MT18FL (carrier copper of RCC film) was removed.
Tenting: a hard mask window (Line/Space pattern of 40 μm/40 μm) was formed on the surface of the cured sample (without the carrier). The sample was then cut to a size of 5 cm×5 cm to serve as the testing coupon.

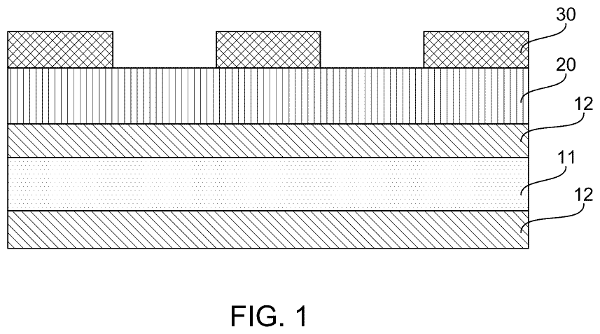

The structure of the testing coupon is shown on FIG. 1. The testing coupon comprises core layer EM526 (11) and its covering copper (12), dielectric layer 20 (curable composition of the present disclosure), and a metal hard mask 30. The following plasma treatment will etch the dielectric layer 20 through the window of the hard mask 30.

### Plasma Etching and Measurement

The coupons of Examples and Comparative Examples were subjected to plasma treatment, and the etching depth was measured using a 3D Optical Microscope (Olympus Lext OLS5100, 50× objective lens). The etching depth is the depth from the surface subtracts the thickness of hard mask. The etching rate was calculated by dividing the etching depth by the processing time. The test results of each coupon are listed in Table C.

TABLE C

| | E1 | E2 | E3 | CE1 | CE2 | CE3 |
|---|---|---|---|---|---|---|
| plasma etching rate (μm/min) | 1.68 | 1.63 | 1.54 | 0.54 | 0.7 | 0.74 |

*Plasma Etching Conditions: Ignition 8 kW; Bias 3 kW; RF Frequency 13.56 MHz; Gas flow rates Oxygen 500 cc/min, CF₄ 500 cc/min, N₂ 50 cc/min; Etching duration 15 minutes

As shown in Table C, the plasma etching rates of Examples 1-3 of the present disclosure are greater than 1.0 μm/min. The plasma etching rate can further reach greater than 1.5 μm/min. In contrast, Comparative Examples 1-3 have relatively low plasma etching rates, and may not be suitable for industry use.

### Measuring Df and CTE of the Resin Sheet

### Sample Preparation

Resin sheets of Examples and Comparative Examples were further processed as follows to prepare a sample for measuring Df and CTE:
Lamination: multiple resin sheets of 10 cm×10 cm size were laminated together to form one dielectric layer with thickness of 60 μm by vacuum laminator. The vacuum laminator was heated to 100° C. and vacuumed for 30 seconds, then pressured to 7 kgf/cm² for 90 seconds at 100° C.
Curing: The laminated sample was cured in an air flow oven with 130° C. for 30 minutes; 180° C. for 30 minutes; and then 200° C. for 90 minutes.
PET film Removal: After curing, the protective layer 38X (PET film) was removed.

Dissipation factor (Df) of the dielectric/insulting layer was measured by resonance cavity method at a frequency of 10 GHz. Coefficient of thermal expansion (CTE) was measured by TA Instruments TMA 650 thermomechanical analyzer. The sample was heated to 280° C., cooled down to room temperature, and then reheated at a rate of 5° C./min with a preload force of 0.098 N. The CTE was calculated from the slope of dimension change to temperature from 50° C. to 100° C. by the second cycle of heating. The test results of each sample are listed in Table D.

TABLE D

| | E1 | E2 | E3 | CE1 | CE2 | CE3 |
|---|---|---|---|---|---|---|
| Df@10 GHz (23° C.) | 0.0024 | 0.0026 | 0.003 | 0.0027 | 0.0033 | 0.0039 |
| CTE (ppm/° C.) | 13 | 21.7 | 28.6 | 21.5 | 30.2 | 33 |

The curable composition of the present disclosure is particularly suitable for manufacturing printed circuit boards (PCBs).

The insulating film with the present curable composition exhibits excellent electrical properties, including low dissipation factor (Df) and a low coefficient of thermal expansion (CTE). Furthermore, the insulating film provides significant advantages in reducing the production time in PCB manufacturing processes that involve a plasma etching step.

Making a PCB with the Curable Composition
Step 1: Preparation of Substrate with Existing Electrical Circuits

A PCB board with existing electrical circuits was prepared using EM526 (a core board with a thickness of 64 μm and a copper thickness of 22 μm, supplied by Elite Electronic Material Co. Ltd.).

### Step 2: Lamination of RCC Coupons on the Substrate

RCC coupons of example 1 were laminated onto the substrate by laminator (Vigor, VLPH-150 ton vacuum laminator). After lamination, the lower layer of the supporting film was removed and the structure from top to bottom consisted of copper, resin, and substrate.

### Step 3: Patterning the Metal to Form a Hard Mask

A photoresist layer was formed by laminating a dry film (Riston® DI61, 15 μm in thickness, manufactured by DuPont Electronics, Inc.) on the copper layer of the substrate from Step 2 using a roll laminator at 100° C., a pressure of 1.4 MPa, and a rolling speed of 1.0 meter/minute.

The photoresist pattern was created using a direct exposure patterning machine (FDi3 from ORC) with a desired pattern. The uncured part of the photoresist layer was stripped and removed by treatment with a 2% Na₂CO₃ solution for 3 minutes, then rinsed with DI water and dried.

The unmasked copper areas were etched away using a sodium persulfate (Na₂S₂O₈) solution (130 g/L) in a conventional horizontal line at 1 m/min speed until completion, followed by rinsing with DI water and drying. The photoresist pattern was then stripped and removed by treatment with a 10% NaOH solution for 90 seconds, followed by rinsing and drying, forming a copper hard mask on the substrate.

### Step 4: Plasma Etching of the Dielectric Layer

The exposed areas of the dielectric layer were removed by plasma etching using a reactive ion etching plasma system (manufactured by Linco Tech). The process gas was a mixture of CF₄ (500 ml/sec), O₂ (500 ml/sec), and N₂ (50 ml/sec), with an ignition power of 8 kW and a DC bias of 3 kW for 20 minutes, to expose a portion of the existing conductor underneath.

### Step 5: Formation of Seed Layer

A seed layer was formed by sputtering copper using a PVD coating machine (manufactured by UVAT Technology Co., model: UHSD-060302T) with fiducial concentrations of copper 4N. The resulting copper layer had a thickness of 0.8 μm.

### Step 6: Addition of Photoresist Pattern Layer

A photoresist layer was formed by laminating a dry film (Riston® DI61, 25 μm in thickness, manufactured by DuPont Electronics, Inc.) on the copper layer using a roll laminator at 100° C., a pressure of 1.4 MPa, and a rolling speed of 1.0 meter/minute.

The photoresist pattern was created using a direct exposure patterning machine (FDi3 from ORC) with a conventional test pattern by the PCB fabricator, including line/space sets at 15 μm/15 μm. The uncured part of the photoresist layer was stripped and removed by treatment with a 2% Na₂CO₃ solution for 3 minutes, rinsed with DI water, and dried.

### Step 7: Filling the Trench and Via by Metal Deposition

Electroplating was applied to fill the trench and via with copper. The coupon was plated to a copper thickness of 22 μm using 23.13 ASF (amplitude per square feet) for 40 minutes with a plating solution (SFP2M from DuPont).

### Step 8: Removal of Photoresist

The photoresist pattern was stripped by treatment with a 10% NaOH solution for 90 seconds.

### Step 9: Removal of Hard Mask Layer

A flash etch to remove the hard mask layer was conducted by:
Dipping the coupon in a 5 vol % sulfuric acid aqueous solution for 20 seconds.
Transferring the coupon to an etchant solution (ST121-M by Chemtronic Technology) for 48 seconds.
Rinsing with DI water to remove residual solution.

After the flash etch process, the new circuit layer with via and conductor line was completed.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A curable composition, comprising:
100 parts by weight of a maleimide resin;
30-150 parts by weight of a cyanate ester;
10-100 parts by weight of a polyphenylene ether oligomer;
2-75 parts by weight of a thermoplastic elastomer;
0.2-25 parts by weight of an epoxy resin;
0.02-15 parts by weight of a curing catalyst;
0.02-100 parts by weight of an additive; and
120-825 parts by weight of inorganic fillers comprising boron nitride particles having a median particle size of 10 μm or less.

2. The curable composition of claim 1, wherein the maleimide resin comprises a maleimide with a biphenyl aralkyl backbone; a bismaleimide derived from a dimer diamine; a bismaleimide including 4,4′-diphenylmethane bismaleimide, 3,3′-diphenylmethane bismale-imide, 1,3 phenylene bismaleimide, 1,4 phenylene bismaleimide, m-xylenebismaleimide, p-xylenebismaleimide, 2,2′-bis[4-(4-maleimidophenoxy)phenyl]-propane, 3,3′-dimethyl-5,5′ diethyl-4,4′-diphenylmethane bismaleimide, 3,3′,5,5′-tetramethyldiphenylmethane bismaleimide, N,N′-(4-methyl-1,3-phenylene) bismaleimide, 1,6-bismaleimidohexane, 1,6′ bismaleimide-(2,2,4-trimethyl) hexane, or 4,4′-diphenyl ether bismaleimide, or a mixture thereof.

3. The curable composition of claim 1, wherein the cyanate ester is a difunctional or polyfunctional compound selected from the group consisting of 2,2-bis(4-cyanatophenyl) propane (bisphenol A-containing cyanate ester), bis(4-cyanatopheny) methane (bisphenol F-containing cyanate ester), dicyclopentadiene-containing cyanate ester, naphthalene-containing cyanate ester, phenolphthalein cyanate ester, adamantane cyanate ester, fluorene cyanate ester, phenol novolac type cyanate ester, and a combination thereof.

4. The curable composition of claim 1, wherein the polyphenylene ether oligomer is a polyphenylene ether oligomer terminated with an acrylate group, an epoxy group, a vinyl group, a vinylbenzyl ether, or a hydroxyl group.

5. The curable composition of claim 1, wherein the thermoplastic elastomer is selected from the group consisting of polybutadiene, ethylene-propylene-diene copolymer (EPDM), butadiene-styrene block copolymer, styrene-isoprene-styrene block polymer (SIS), styrene-ethylene-propylene-styrene block copolymer (SEPS), styrene-ethylene-butylene-styrene copolymer (SEBS), and modified products thereof; wherein the polymer/copolymer is modified with carboxylic acid groups and/or maleic anhydride groups.

6. The curable composition of claim 1, wherein the epoxy resin is selected from the group consisting of bisphenol A type epoxy, bisphenol F type epoxy, glycidyl amine type epoxy, biphenyl type epoxy, naphthalene type epoxy, anthracene type epoxy, fluorene type epoxy, biphenyl aralkylphenol type epoxy, dicyclopentadiene type epoxy, trihydroxyphenylmethane type epoxy, naphthol aralkyl type epoxy, phenol aralkyl type epoxy, phenol novolac type epoxy, cresol novolac type epoxy, bisphenol novolac type epoxy, naphthol-cresol novolac type epoxy, naphthalenediol novolac type epoxy, hydrogenated modified epoxy, halogen modified epoxy, and a combination thereof.

7. The curable composition of claim 1, wherein the curing catalyst is selected from the group consisting of an alkyl amine type catalyst, a pyridine type catalyst, an imidazole type catalyst, a piperidine type catalyst, a metal-based curing catalyst, and a combination thereof.

8. The curable composition of claim 1, wherein the additive is selected from the group consisting of adhesion promoter, antioxidant, colorant, defoamer, flame retardant, polymerization inhibitor, silane coupling agent, solvent, surface conditioner, thickener, ultraviolet absorber, and a combination thereof.

9. The curable composition of claim 1, wherein the additive is a flame retardant selected from the group consisting of a brominated flame retardant, a phosphorus flame retardant, a nitrogen flame retardant, and a combination thereof.

10. The curable composition of claim 1, wherein the additive is a solvent comprising cyclohexanone, cyclopentanone, isophorone, methyl ethyl ketone, methyl isobutyl ketone, toluene, or a combination thereof.

11. An insulating film for fabricating a printed circuit board, comprising sequentially:
a support film,
a resin layer composed of the curable composition of claim 1, and
a protective film,
wherein the resin layer has a thickness of 10 μm to 60 μm.

12. The insulating film of claim 11, wherein the support film and the protective film are each independently composed of a polymeric material selected from the group consisting of polyethylene, polypropylene, polyvinyl chloride, polyethylene terephthalate, polyethylene naphthalate, polycarbonate, and polyimide.

13. The insulating film of claim 11, wherein the support film is a metallic foil selected from the group consisting of Au, Ag, Cu, Al, and alloys thereof.

14. The insulating film of claim 11, wherein the resin layer after curing has a dissipation factor (Df) of 0.006 or less when measured at 10 GHz and 23° C., and the curing is conducted at 100° C. to 250° C. for 60 minutes to 240 minutes.

15. The insulating film of claim 11, wherein the resin layer after curing has a coefficient of thermal expansion (CTE) of 40 ppm/K or less between 30° C. to 120° C., and the curing is conducted at 100° C. to 250° C. for 60 minutes to 240 minutes.

16. The insulating film of claim 11, wherein the resin layer after curing has a plasma etching rate of 1 μm/min or more, and the plasma etching is performed under a chamber pressure of 2 Pa (15 mtorr) by applying a radiofrequency (RF) power of 13.56 MHz, an ignition power of 8000 Watts, a DC bias of 3000 Watts with a gas mixture of oxygen, tetrafluoromethane (carbon tetrafluoride, CF4) and nitrogen at a ratio of 10:10:1, and a flow rate of 1050 mL/sec for 15 minutes, and the curing is conducted at 100° C. to 250° C. for 60 minutes to 240 minutes.

17. A printed circuit board, comprising an insulating layer that is a cured product of the curable composition of claim 1.

18. The printed circuit board of claim 17, wherein the circuit is fabricated by a method comprising a plasma etching step for via and/or trench formation.
